(19) United States
(12) Patent Application Publication
(10) Pub. No.: US 2010/0102452 A1
(43) Pub. Date: Apr. 29, 2010

(54) METHOD FOR FABRICATING SEMICONDUCTOR DEVICE AND SEMICONDUCTOR DEVICE

(76) Inventor: Shinichi NAKAO, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/537,759

(22) Filed: Aug. 7, 2009

(30) Foreign Application Priority Data
Oct. 24, 2008 (JP) 2008-273818

(51) Int. Cl. H01L 23/48; H01L 21/768

(52) U.S. Cl. 257/773; 438/653; 257/E21.584; 257/E23.011

(57) ABSTRACT

A method for fabricating a semiconductor device, includes forming a dielectric film above a substrate; forming a cap film, in which pores are formed, on the dielectric film; forming an opening in the cap film and the dielectric film; depositing a conductive material inside the opening; and forming a diffusion barrier film for preventing diffusion of the conductive material on the cap film, after the conductive material is deposited inside the opening, in such a way that a portion of the diffusion barrier film intrudes into the cap film and that a portion of the pores remains.

### CROSS-REFERENCE TO RELATED APPLICATION

This application is based upon and claims the benefit of priority from prior Japanese Patent Application No. 2008-273818 filed on Oct. 24, 2008 in Japan, the entire contents of which are incorporated herein by reference.

### BACKGROUND OF THE INVENTION

1. Field of the Invention

The present invention relates to a method for fabricating a semiconductor device and a semiconductor device and, for example, relates to a configuration of an interlayer dielectric film in copper (Cu) wiring layer and a method for fabricating thereof.

2. Related Art

In recent years, new microprocessing technologies have been developed accompanying an increasing scale of integration and higher performance of semiconductor integrated circuits (LSI). Particularly, to realize faster LSI, there is a recent trend to replace conventional aluminum (Al) alloys as a wiring material by low-resistance copper (Cu) or Cu alloys (hereinafter, referred to as Cu together). Since it is difficult to microprocess Cu by the dry etching method, which is frequently used for forming Al alloy wires, the so-called damascene method is adopted, by which an embedded wire is formed by depositing a Cu film on a dielectric film in which a groove is formed and then, removing the Cu film excluding that embedded in the groove by chemical-mechanical polishing (CMP). The Cu film is generally formed by forming a thin seed layer by the sputter process or the like and then forming a laminated layer to a thickness of about several hundred nm by electro-plating method. Further, when a multilayer Cu wire is formed, a dielectric film is deposited on a lower wire and predetermined via holes are formed in which Cu as a plug material is embedded to lead to an upper wire.

Recently, using a low dielectric constant material film (low-k film) having a low relative dielectric constant as an interlayer dielectric film has been discussed. That is, an attempt is being made to lower a parasitic capacitance between wires by using a low dielectric constant material film (low-k film) whose relative dielectric constant k is 2.6 or less, instead of a silicon oxide film (SiO₂) whose relative dielectric constant k is about 4.2. Particularly, a process using a so-called porous dielectric film having microscopic holes in the dielectric film has been developed to make the dielectric constant lower.

In an LSI metal wire structure using the damascene method, a dense cap film layer is usually laminated on a low dielectric constant dielectric film. This is because it is difficult to directly process a low dielectric constant dielectric film layer that has a low density and low strength when the dielectric film is processed using the reactive ion etching (RIE) method or CMP method. Thus, a low dielectric constant dielectric film layer is typically processed in a state in which a low dielectric constant dielectric film is covered with a dense cap film layer.

However, the dense cap film layer that is excellent in workability has a higher relative dielectric constant than the low dielectric constant dielectric film. As a result, there is a problem that the high relative dielectric constant poses an obstacle to lowering of dielectric constant of each wiring layer in a multilayer interconnection structure. Thus, an attempt has been made to prevent an increase in the relative dielectric constant of the whole interlayer dielectric film due to the cap film layer in each wiring layer and also to further lower the dielectric constant of the whole interlayer dielectric film.

For example, a technique described below is proposed. The CMP processing is performed on a low dielectric constant dielectric film being covered with a high dielectric constant cap film layer, and then, only the cap film layer is removed. Accordingly, a Cu wire protrudes from the surface of the low dielectric constant dielectric film by the thickness of the cap film. Then, a diffusion barrier film is formed to a thickness thinner than that of the cap film to cover the low dielectric constant dielectric film and the protruding Cu wire surface and remaining protruding Cu wire portions are covered with a low dielectric constant dielectric film as an upper layer (see US2005/0253266A1, for example). Accordingly, a top edge of the Cu wire is insulated by a laminated film of the diffusion barrier film and the low dielectric constant dielectric film as its upper layer (such as a via plug layer) and remaining Cu wire portions are insulated by the low dielectric constant itself dielectric film and thus, it is expected that the dielectric constant can be made lower than that obtained by insulating the top edge of the Cu wire by the cap film. However, according to such a technique, a diffusion barrier film generally having a high relative dielectric constant is present between Cu wires and therefore, the relative dielectric constant k of interlayer dielectric in the whole wiring layer usually becomes higher than the value of the relative dielectric constant k of the low dielectric constant dielectric film itself.

If, as another technique, for example, the CMP processing is performed on a low dielectric constant dielectric film being covered with a cap film layer, and in this state, polishing is performed until the cap film layer is removed, the whole sides of the Cu wires will be covered with the low dielectric constant dielectric film itself as a result and therefore, an increase in the in the relative dielectric constant due to the cap film layer can be prevented. However, according to such a technique, the value of the relative dielectric constant k at the top edge of interlayer dielectric can be made only equivalent to the k value of the low dielectric constant dielectric film and therefore, it is difficult to further lower the dielectric constant.

Further, the top edge of the Cu wire where the cap film layer exists is a portion in which an electric field generated between neighboring wires in the same layer is particularly concentrated. A Cu ion drift is more likely to occur at such top edge of the Cu wire where an electric field is concentrated. As a result, there is a problem that the TDDB (Time Dependent Dielectric Breakdown) life is shortened. References to the TDDB life of such a Cu damascene wire or the like are made in the literature (See, for example, “TDDB Improvement in Cu Metallization Under Bias Stress”, Proceedings of International Reliability Physics Symposium 2000, P. 339 and “Bulk and Interfacial Leakage Current in Dielectric Degradation of Copper Damascene Interconnects”, Proceedings of Advanced Metallization Conference 2004, P. 411) To prolong the TDDB life, suppression of the Cu ion drift is desired. However, no technique to adequately solve such a problem has been established.

### BRIEF SUMMARY OF THE INVENTION

In accordance with one aspect of the present invention, a method for fabricating a semiconductor device, includes forming a dielectric film above a substrate; forming a cap film, in which pores are formed, on the dielectric film; forming an opening in the cap film and the dielectric film; depositing a conductive material inside the opening; and forming a diffusion barrier film for preventing diffusion of the conductive material on the cap film, after the conductive material is deposited inside the opening, in such a way that a portion of the diffusion barrier film intrudes into the cap film and that a portion of the pores remains.

In accordance with another aspect of this invention, a method for fabricating a semiconductor device, includes forming a dielectric film above a substrate; forming a cap film by using a material containing porogen components on the dielectric film so that the porogen components remain; forming an opening in the cap film and the dielectric film; depositing a conductive material inside the opening; and obtaining a porous cap film having a relative dielectric constant lower that that of the dielectric film by removing the porogen components from inside the cap film after the conductive material is deposited inside the opening.

In accordance with a further aspect of the invention, a semiconductor device, includes a dielectric film formed above a substrate; a cap film formed on the dielectric film and having a relative dielectric constant lower than that of the dielectric film; and a wire arranged in such a manner that the cap film and the dielectric film are positioned on a side of the wire.

### BRIEF DESCRIPTION OF THE DRAWINGS

FIG. 1 is a flow chart showing principal parts of a method for fabricating a semiconductor device according to a first embodiment.

FIGS. 2A to 2D are process sectional views showing processes performed corresponding to the flow chart in FIG. 1.

FIGS. 3A to 3C are process sectional views showing processes performed corresponding to the flow chart in FIG. 1.

FIGS. 4A to 4C are process sectional views showing processes performed corresponding to the flow chart in FIG. 1.

FIG. 5 is a conceptual diagram showing a state in which a diffusion barrier film of the first embodiment intrudes into a cap film.

FIG. 6 is a diagram showing a result of simulating a relationship between a relative dielectric constant of the cap film and electric field strength of an interface between the diffusion barrier film and the cap film of the first embodiment.

FIG. 7 is a prediction diagram showing a relationship between the relative dielectric constant of the cap film and TDDB life of the first embodiment.

FIGS. 8A and 8B are conceptual diagrams respectively showing relationships between electric field strength and a Cu drift of the cap film of the first embodiment and of a conventional cap film.

FIGS. 9A and 9B are conceptual sectional views comparing conditions of the Cu drift depending on presence/absence of intrusion into the diffusion barrier film of the first embodiment.

FIG. 10 is a diagram showing a result of simulating a relationship between the relative dielectric constant of the cap film of the first embodiment and the effective relative dielectric constant of whole of one wiring layer.

FIG. 11 is a flow chart showing principal parts of the method for fabricating a semiconductor device in a second embodiment.

FIGS. 12A to 12C are process sectional views showing processes performed corresponding to the flow chart in FIG. 11.

### DETAILED DESCRIPTION OF THE INVENTION

In each embodiment below, a semiconductor device capable of making the dielectric constant lower or increasing TDDB life and a method for fabricating thereof are described.

### First Embodiment

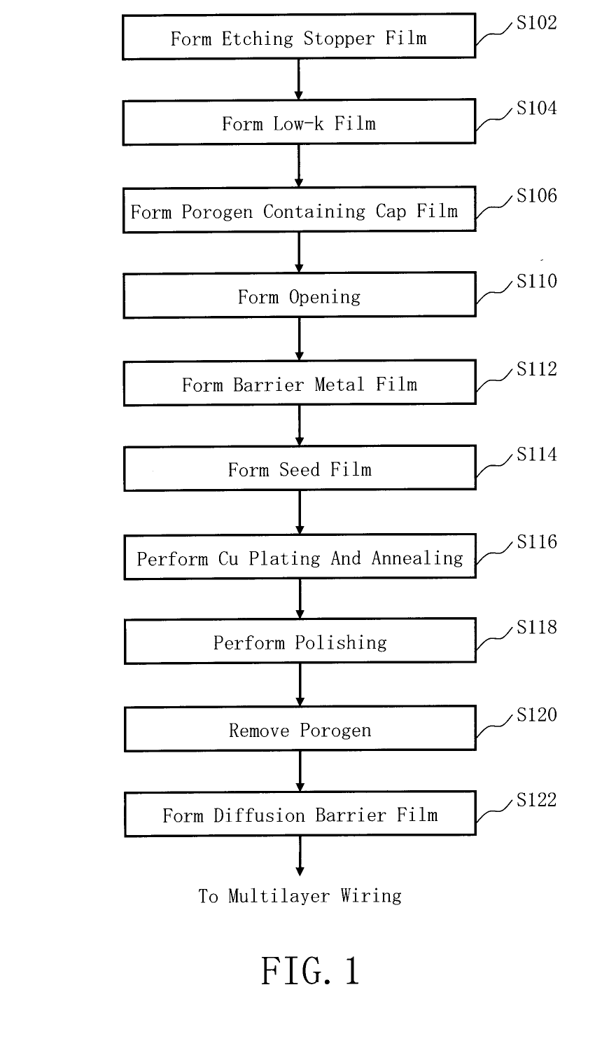

The first embodiment will be described below with reference to drawings. FIG. 1 illustrates a flowchart showing principal parts of a method for fabricating a semiconductor device of the first embodiment. As shown in FIG. 1, a series of processes including an etching stopper film formation process (S102), a low-k film formation process (S104), a porogen containing cap film formation process (S106), an opening formation process (S110), a barrier metal film formation process (S112), a seed film formation process (S114), a plating and annealing process (S116), a polishing process (S118), a porogen removal process (S120), and a diffusion barrier film formation process (S122) is performed.

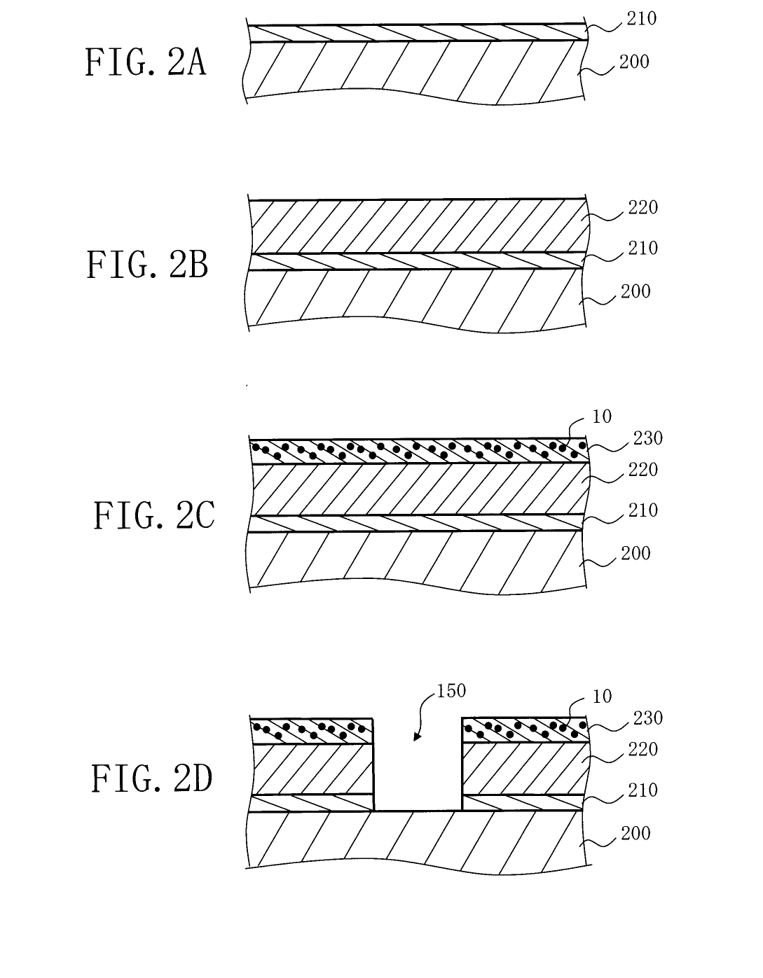

FIGS. 2A to 2D are process sectional views showing processes performed corresponding to the flow chart in FIG. 1. FIGS. 2A to 2D show processes from the etching stopper film formation process (S102) to the opening formation process (S110).

As shown in FIG. 2A, as the etching stopper film formation process (S102), an etching stopper film 210 is formed on a substrate 200 by the chemical vapor deposition (CVD) method to a thickness of, for example, 20 to 40 nm. For example, silicon carbonitride (SiCN), silicon carbide (SiC), or nonporous dense silicon carboxide (dense SICO) is preferable as a material of the etching stopper film. The formation method is not limited to the CVD method and any other method may be used to form the etching stopper film 210. A silicon wafer whose diameter is 300 mm, for example, may be used as the substrate 200. Here, a contact plug layer or device portion is not illustrated. Moreover, a layer having various kinds of semiconductor devices or arrangement, which are not illustrated, such as other metal wires or via plugs may be formed on the substrate 200. Also, any other layer may be formed.

As shown in FIG. 2B, as the low-k film formation process (S104), a low-k film 220 is formed using a porous low dielectric constant dielectric material to a thickness of, for example, 100 nm. By forming the low-k film 220, a dielectric film whose relative dielectric constant k is about 2.4 to 3.0 can be obtained. The low-k film 220 becomes a main dielectric film of an interlayer dielectric film for one wiring layer. Here, as an example, a porous SiOCH film to be a low dielectric constant dielectric material whose relative dielectric constant is less than 2.5 is formed by using the CVD method. The formation method is not limited to the CVD method and, for example, the SOD (spin on dielectric coating) method, in which a solution is spin-coated and heated to form a thin film, may also be preferably used. A porous methyl silsesquioxane (MSQ) may be used as an example of a material of the low-k film 220 formed by the SOD method. In addition to MSQ, for example, the low-k film 220 may be formed by using at least a kind of film selected from a group consisting of: a film having siloxane backbone structures such as polymethyl siloxane, polysiloxane, and hydrogen silsesquioxane; a film having organic resin as a main component such as polyarylene ether, polybenzo oxazole; and polybenzo cyclobutene, and a porous film such as a porous silica film. Using such materials of the low-k film 220, a low dielectric constant of less than 2.5 can be obtained. With the SOD method, the low-k film 220 can be formed by forming a film on a wafer on a spinner, baking the wafer on a hot plate in a nitrogen atmosphere, and finally curing the wafer on the hot plate at temperature higher than the temperature during baking in nitrogen atmosphere. A porous dielectric film having predetermined physical properties can be obtained by appropriately adjusting low-k materials or formation conditions.

As shown in FIG. 2C, as the porogen containing cap film formation process (S106), a cap film 230 is formed on the low-k film 220 using a material containing porogen components 10 to a thickness of, for example, 20 to 40 nm. For example, the CVD method is used to form the cap film 230. The cap film 230 is formed to have a thickness thinner than that of the low-k film 220. Silicon carboxide containing hydrogen (SiOCH) that also contains the porogen components 10 is preferable as a material of the cap film 230. As the porogen components 10, a polymer containing carbon (C) and hydrogen (H), for example, C₁₀H₁₆ is preferable.

As the formation method of the cap film 230, for example, a mixed gas containing Methyl-Di-Ethoxy-Silane, alpha-terpinene (C₁₀H₁₆), Oxygen (O₂), and Helium (He) is introduced into a chamber (not shown) and the substrate 200 on which the low-k film 220 is formed is heated to, for example 250° C. and high-frequency power is supplied to a lower electrode and an upper electrode in the chamber in a state in which the pressure in the chamber is maintained at, for example, 1.3×10³ Pa (10 Torr) or less to generate plasma. Methyl-Di-Ethoxy-Silane is a gas for forming main backbone components and alpha-terpinene is a gas for forming porogen components. Accordingly, the cap film 230 of SiOCH film having organic siloxane as a main backbone component is formed on the low-k film 220. At this point, alpha-terpinene contained in the mixed gas is polymerized by plasma to form polymeric organic substance. The polymeric organic substance is the porogen components 10 and is incorporated into the SIOCH film.

As an organic silicon gas for forming main backbone components, at least one of Di-Methyl-Silane, Tri-Methyl-Silane, Tetra-Methyl-Silane, Di-Methyl-Phenyl-Silane, Tri-Methyl-Silyl-Acetylene, Mono-Methyl-Di-Ethoxy-Silane, Di-Methyl-Di-Ethoxy-Silane, Tetra-Methyl-Cyclo-Tetra-Siloxane, and Octa-Methyl-Cyclo-Tetra-Siloxane can be used.

As a gas for forming porogen components, on the other hand, at least one of Methane, Ethylene, Propylene, Alpha-Terpinene, Gamma-Terpinene, and Limonene can be used.

Here, the SIOCH film is formed by the CVD method, but the formation method is not limited to this method. For example, the SOD method, in which a solution containing porogen components is spin-coated and heated to form a thin film, may also be preferably used. MSQ can be used as an example of a material of the cap film 230 having low dielectric constant formed by the SOD method. In addition to MSQ, for example, the cap film 230 may be formed by using at least one film selected from a group consisting of: a film having siloxane backbone structures such as polymethyl siloxane, polysiloxane, and hydrogen silsesquioxane; a film having organic resin as a main component such as polyarylene ether, polybenzo oxazole, and polybenzo cyclobutene, and a porous film such as a porous silica film. In the SOD method, for example, a film is formed on a wafer on a spinner, and the wafer is baked on a hot plate in a nitrogen atmosphere to form the cap film 230 of an SiOCH film having, for example, organic siloxane uniformly containing the porogen components 10 as a main backbone component. Regardless of which material of the low dielectric constant dielectric film is used, a low dielectric constant of, for example, 2.0 or less, which has a lower relative dielectric constant k than that of the low-k film 220, can be obtained in the end.

In the first embodiment, the porogen components 10 in the cap film 230 are not removed immediately after film formation, and only main backbone formation is performed here. For example, after a film is formed on the low-k film 220 by the CVD method or the SOD method, the film is heated at 200 to 300° C., whereby a main backbone can be formed. Since, in such a state, the porogen components 10 are not removed and left, no pore (hole) is formed in the film. Accordingly, the film is dense, and thus the film can maintain a state where mechanical strength thereof is stronger than that of a porous film such as the low-k film 220.

As shown in FIG. 2D, as the opening formation process (S110), an opening 150 to be a wire groove or a via hole is formed by continuously etching the exposed cap film 230 and the low-k film 220 as a lower layer thereof in substantially the same width by the anisotropic etching method using a resist pattern (not shown) as a mask. In this case, the etching is performed using the etching stopper film 210 as an etching stopper. Then, the etching stopper film 210 is etched to form the opening 150 reaching the substrate 200. By using the anisotropic etching method for removal, the opening 150 can be formed substantially perpendicular to a surface of the substrate 200. The opening 150 maybe formed by, for example, the reactive ion etching (RIE) method. Since the cap film 230 having sufficient mechanical strength serves as a mask for the low-k film 220 during etching, the low-k film 220 can be protected.

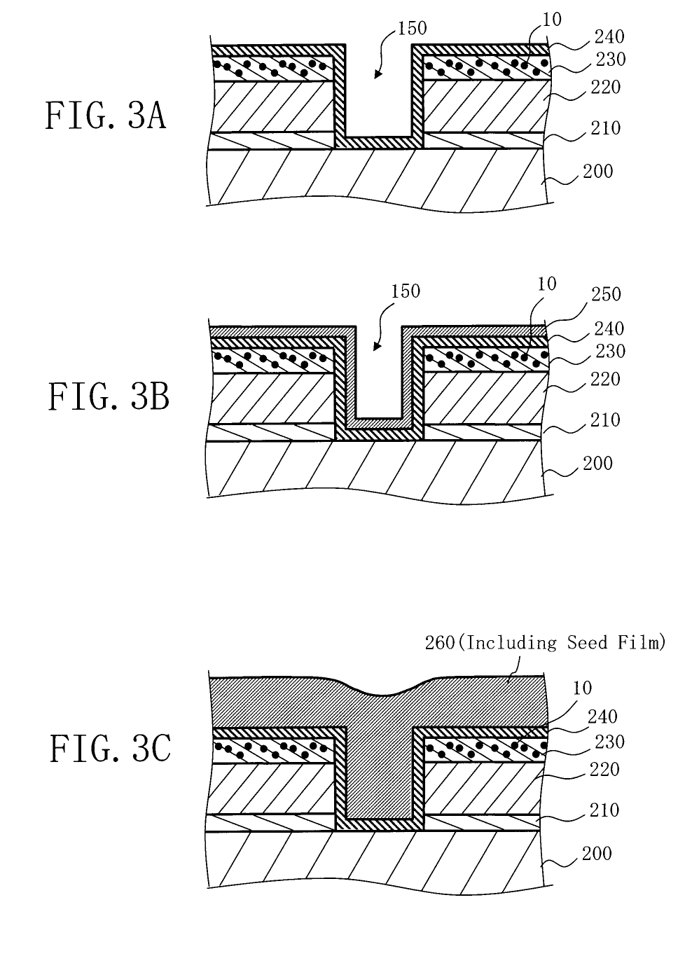

FIGS. 3A to 3C are process sectional views showing processes performed corresponding to the flow chart in FIG. 1. FIGS. 3A to 3C show processes from the barrier metal film formation process (S112) to the plating and annealing process (S116).

As shown in FIG. 3A, as the barrier metal film formation process (S112), a barrier metal film 240 if formed using a barrier metal material as an example of conductive material on the inner surface of the opening 150 formed by etching and on the surface of the cap film 230. A TaN film is deposited to a thickness of, for example, 5 nm in a sputtering apparatus using the sputter process to form the barrier metal film 240. The deposition method of a barrier metal material is not limited to the PVD method and the atomic layer vapor deposition (the atomic layer deposition (ALD), or the atomic layer chemical vapor deposition (ALCVD) ) method or the CVD method may also be used. The coverage factor can be made better than that when the PVD method is used. As materials of the barrier metal film 240, in addition to TaN, metals such as tantalum (Ta), titanium (Ti), ruthenium (Ru), tungsten (W), zirconium (Zr), aluminum (Al), and niobium (Nb), and nitride of these metals represented by titanium nitride (TiN) and tungsten nitride (WN), and other materials containing the above metals can be used alone or in a laminated structure.

As shown in FIG. 3B, as the seed film formation process (S114), a Cu thin film to be a cathode electrode in the next process, the electro-plating process, is deposited (formed) on the inner wall of the opening 150 and on the surface of the substrate 200 where the barrier metal film 240 is formed by the physical vapor deposition (PVD) method such as sputtering as a seed film 250.

As shown in FIG. 3C, as the plating and annealing process (S116), the seed film 250 is used as a cathode electrode to deposit a Cu film 260 as an example of conductive material on the surface of the opening 150 and the substrate 200, on which the seed film 250 is formed, by the electrochemical growth method such as electro-plating. Here, the Cu film 260 of the thickness of, for example, 200 nm is deposited and after the deposition, annealing processing is performed, for example, at 250° C. for 30 minutes.

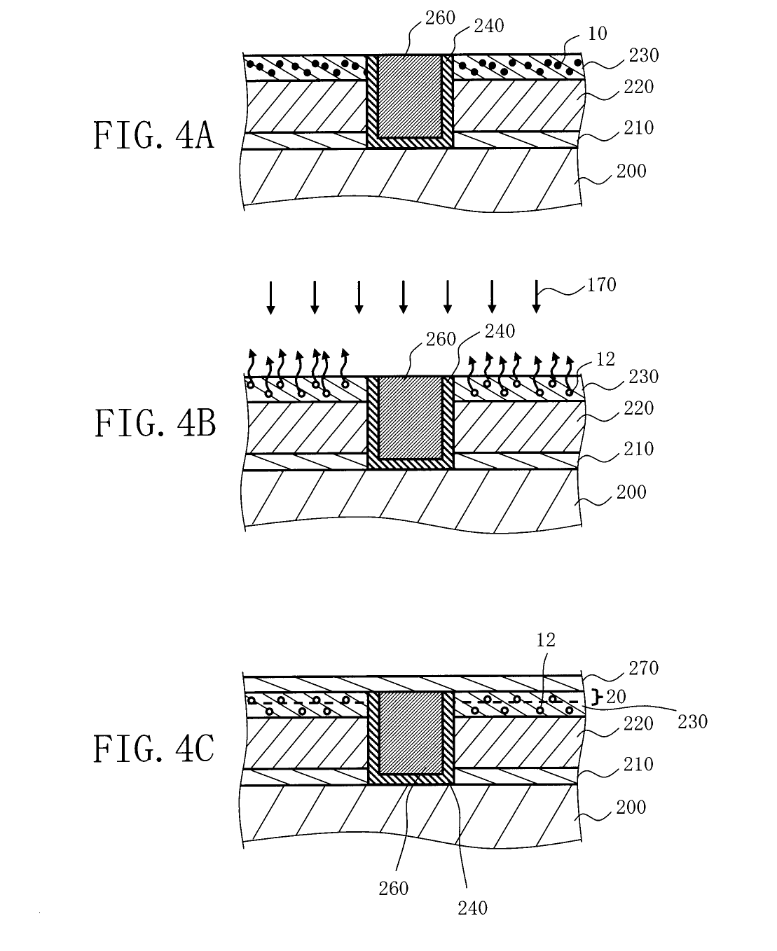

FIGS. 4A to 4C are process sectional views showing processes performed corresponding to the flow chart in FIG. 1. FIGS. 4A to 4C show processes from the polishing process (S118) to the diffusion barrier film formation process (S122).

As shown in FIG. 4A, as the polishing process (S118), the surface of the substrate 200 is polished by the CMP method to remove by polishing the Cu film 260 including the seed film 250 to be a wiring layer and the barrier metal film 240 deposited on the surface excluding the opening. As a result, as shown in FIG. 4A, the surface of the Cu film 260 and the surface of the cap film 230 are planarized to make a common surface. With the above processes, the Cu wire can be formed. Since the cap film 230 with sufficient mechanical strength is formed on the low-k film 220 during polishing, since the low-k film 220 can be protected.

Here, the porogen components 10 remain in the cap film 230 in a state shown in FIG. 4A and the relative dielectric constant k is higher that that of the low-k film 220 and thus, the porogen components 10 will be removed in the next process.

As shown in FIG. 4B, as the porogen removal process (S120), the porogen components 10 are removed from the cap film 230 whose surface is exposed. The porogen components 10 are removed, for example, by performing curing through irradiation of an electron beam (EB). More specifically, the substrate 200, in a state where the surface of the cap film 230 is exposed, is heated to 350 to 400° C. inside a chamber (not shown) while the pressure is maintained at, for example, 1.3×10³ Pa (10 Torr) or less. Next, an Argon (Ar) gas is introduced into the chamber and the pressure inside the chamber is maintained constant. After the pressure becomes constant, the cap film 230 is irradiated with an electron beam 170. For example, the electron beam 170 is irradiated under conditions of acceleration energy of 10 to 20 keV. Pores 12 are formed inside the cap film 230 by removing the porogen components 10 that have become bubbles due to irradiation of the electron beam. Accordingly, the porous cap film 230 that has the relative dielectric constant k of, for example, 2.0 or less, which is lower than that of the low-k film 220, and that has the pores 12 uniformly distributed throughout thereof can be obtained. In other words, by removing the porogen components 10, if, for example, the cap film 230 and the low-k film 220 are made of the same SiOCH film, the density of the cap film 230 becomes lower than that of the low-k film 220. For example, the cap film 230 having density of 1.0 to 1.2 g/cm³ can be formed as opposed to the low-k film 220 having density of 1.2 to 1.4 g/cm³.

In addition, instead of electron beam irradiation, the porogen components 10 may preferably be removed by performing curing through irradiation of ultraviolet rays. More specifically, the substrate 200, in a sate where the surface of the cap film 230 is exposed, is heated to 350 to 400° C. inside a chamber (not shown) while the pressure is maintained at, for example, 1.3×10³ Pa (10 Torr) or less. Next, an Ar gas is introduced into the chamber and the pressure inside the chamber is maintained constant. After the pressure becomes constant, the cap film 230 is irradiated with ultraviolet rays. Here, the cap film 230 is irradiated with ultraviolet rays having a wavelength region of, for example, 200 nm to 300 nm. Through the operations, the porogen components 10 become bubbles, thereby removed. Accordingly, the porous cap film 230 (porous SiOCH film) that has the relative dielectric constant k of, for example, 2.0 or less, which is lower than that of the low-k film 220, and that has the pores 12 uniformly distributed throughout thereof can be obtained. Similarly, if, for example, the cap film 230 and the low-k film 220 are made of the same SiOCH film, the density of the cap film 230 becomes lower than that of the low-k film 220. For example, the cap film 230 having density of 1.0 to 1.2 g/cm³ can be formed as opposed to the low-k film 220 having density of 1.2 to 1.4 g/cm³.

When the porogen components 10 are removed from the cap film 230, the low-k film 220 has no porogen component and thus, no film contraction occurs in the low-k film 220 when the porogen components 10 are removed from the cap film 230. Thus, in the first embodiment, a risk of film contraction can be avoided even if the low-k film 220 and the cap film 230 are both formed as porous films.

As shown in FIG. 4C, as the diffusion barrier film formation process (S122), a diffusion barrier film 270 (barrier film) to prevent diffusion of Cu is formed by using the CVD method on the cap film 230 in such a way that a portion of the diffusion barrier film 270 intrudes into the cap film 230 and that a portion of the pores 12 of the cap film 230 remains. For example, the diffusion barrier film 270 is formed on the cap film 230 to a thickness of 20 to 40 nm. For example, silicon carbonitride (SiCN), silicon carbide (SiC), or nonporous silicon carboxide (dense SiCO) is preferable as the material of the diffusion barrier film 270. The formation method is not limited to the CVD method and any other method may be used to form the diffusion barrier film 270. When a Cu wiring layer and a via plug layer as upper layers or a dual damascene wire layer, in which a Cu wire and a via plug as upper layers are integrally formed, is formed, the diffusion barrier film 270 also functions as an etching stopper film for forming an opening in an interlayer dielectric film of the upper layers.

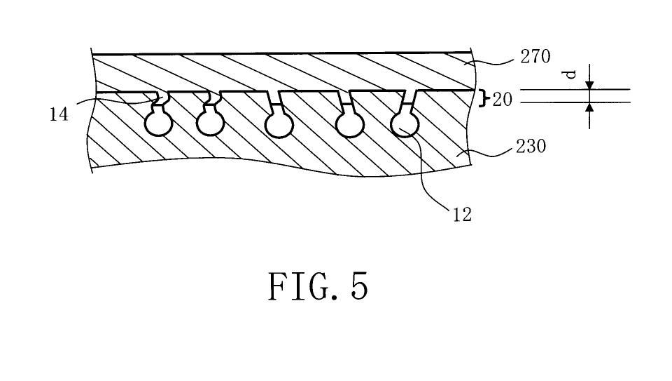

FIG. 5 is a conceptual diagram showing a state in which a diffusion barrier film of the first embodiment intrudes into a cap film. As shown in FIG. 5, the cap film 230 has vent holes 14 used as passages when the porogens 10 volatilize and the pores 12 at positions occupied by the porogens 10 formed therein. That is, the vent holes 14 are formed uniformly on the whole surface of the cap film 230. The diffusion barrier film 270 is formed in such a way that a portion thereof intrudes into the vent holes 14 formed on the whole surface of the cap film 230 and the pores 12 thereunder. If, for example, the size of the vent holes 14 formed on the surface of the cap film 230 is 2 to 4 nm, the size of the CVD gas when the diffusion barrier film 270 is formed is 1 nm or less so that the gas can intrude into the vent holes 14.

Here, it is preferable that a depth d of an intrusion region 20 where the diffusion barrier film 270 intrudes into the cap film 230 is a depth that allows formation of the intrusion region 20 uniformly on the whole surface of the cap film 230 and within a range with which the relative dielectric constant k of the cap film 230 does not exceed that of the low-k film 220, which is the main dielectric film. The diffusion barrier film 270 is preferably formed so as to intrude into the cap film 230 by, for example, 5 to 10 nm. The depth d can be controlled, for example, by adjusting the bias voltage or the like when the diffusion barrier film 270 is formed by the PE-CVD method. Alternatively, the depth d may preferably be controlled by, for example, adjusting the molecular weight of a process gas to be used when the diffusion barrier film 270 is formed by the CVD method. Alternatively, the depth d may be controlled by adjusting the amount of the porogen components 10 contained in the cap film 230. The porogen components 10 are normally distributed in the cap film 230 in a state where a plurality of molecules are integrated. Thus, if the amount of the porogen components 10 is decreased, the size of the formed pores 12 and that of the vent holes 14 become smaller so that intrusion of the gas can be suppressed. Thus, the intrusion depth can be made shallower. Conversely, if the amount of the porogen components 10 is increased, the size of the formed pores 12 and that of the vent holes 14 become larger so that penetration of the gas can be promoted. Thus, the intrusion depth can be made deeper. Alternatively, the depth d may be controlled by adjusting the dispersion ratio of the porogen components 10 contained in the cap film 230.

According to the processes described above, a Cu wiring layer for one layer as shown in FIG. 4C in which the cap film 230 whose relative dielectric constant k is lower than that of the low-k film 220 and the low-k film 220 are arranged to be positioned on the side of the Cu film 260 to be a Cu wire can be formed.

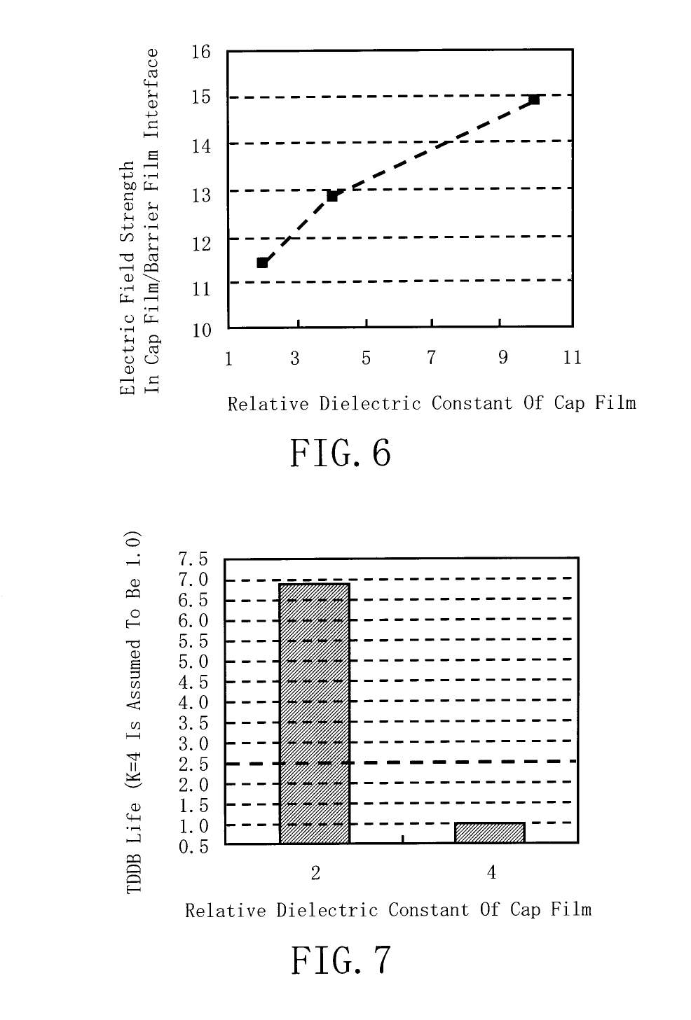

FIG. 6 is a diagram showing a result of simulating a relationship between the relative dielectric constant of the cap film and electric field strength in an interface between the diffusion barrier film and the cap film of the first embodiment. In FIG. 6, the vertical axis shows the electric field strength in the interface between the diffusion barrier film 270 and the cap film 230 and the horizontal axis shows the relative dielectric constant of the cap film 230. Electric field strength values obtained by a two-dimensional electromagnetic simulator are used. It is assumed that the relative dielectric constant k of the low-k film 220 is 2.7, that of the diffusion barrier film 270 is 3.7 and a potential difference applied to a dielectric film space of the width of 70 nm between Cu wires is 1 V. It can be seen that, as a result of simulation, by making the relative dielectric constant k of the cap film 230 smaller, electric field strength in the interface can also be made weaker accordingly as shown in FIG. 6.

FIG. 7 is a prediction diagram showing a relationship between the relative dielectric constant of the cap film and the TDDB life of the first embodiment. In FIG. 7, the vertical axis shows the TDDB life and the horizontal axis shows the relative dielectric constant of the cap film 230. Under the same conditions as those for evaluation in FIG. 6, about seven times prolongation can be estimated when the relative dielectric constant k of the cap film 230 is 2 compared with the case of the relative dielectric constant k is 4. This can be considered to result from a reduced amount of drift of Cu ions, to be described below, caused by weakened electric field strength as shown in FIG. 6.

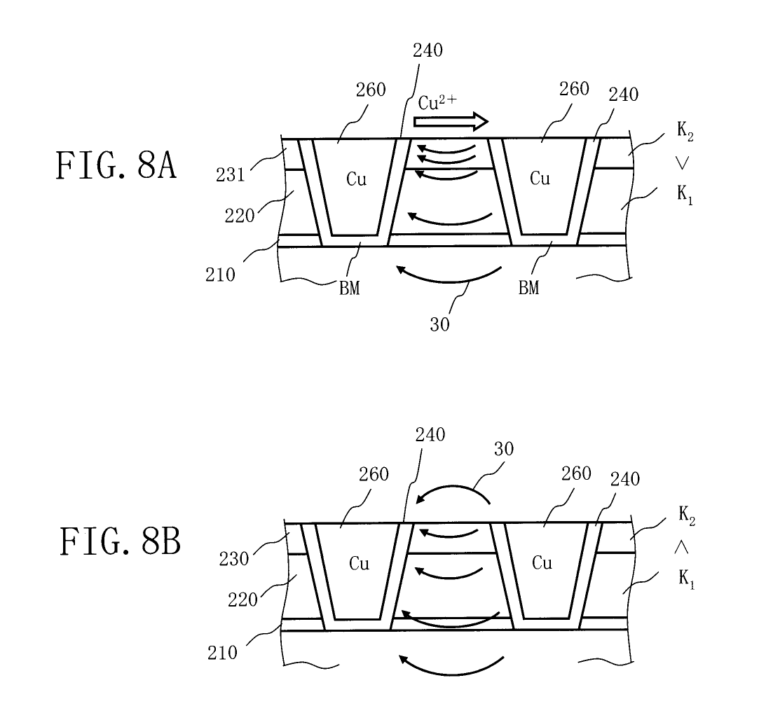

FIGS. 8A and 8B are conceptual diagrams respectively showing relationships between electric field strength and a Cu drift in the cap film of the first embodiment and of a conventional cap film. A conventional cap film 231 has a relative dielectric constant k2 sufficiently greater than a relative dielectric constant k1 of the low-k film 220. In such a case, as shown in FIG. 8A, an electric field 30 between two Cu wires represented by the Cu film 260 becomes relatively dense in a cap film 231 having a large relative dielectric constant, particularly in an upper part thereof, that is, at the top edge of the Cu wire and the electric field strength becomes the strongest. Thus, Cu ions are more likely to drift at the top edge of the Cu wire. In contrast, the cap film 230 of the first embodiment has the relative dielectric constant k2 that is smaller than the relative dielectric constant k1 of the low-k film 220. In such a case, as shown in FIG. 8B, the electric field 30 between two Cu wires represented by the Cu film 260 is spread out and the electric field 30 becomes relatively sparse at the top edge of the Cu wire and the electric field strength becomes weaker. Thus, a drift of Cu ion sat the top edge of the Cu wire can be suppressed. Moreover, both sides and the bottom of the Cu wire are covered with the barrier metal film 240 and thus, a drift of Cu ions in other portions than the top edge of the Cu wire is originally less likely to occur.

By making the relative dielectric constant k2 of the cap film 230 smaller than the relative dielectric constant k1 of the low-k film 220, as described above, a drift of Cu ions can be suppressed. As a result, the TDDB life can be prolonged.

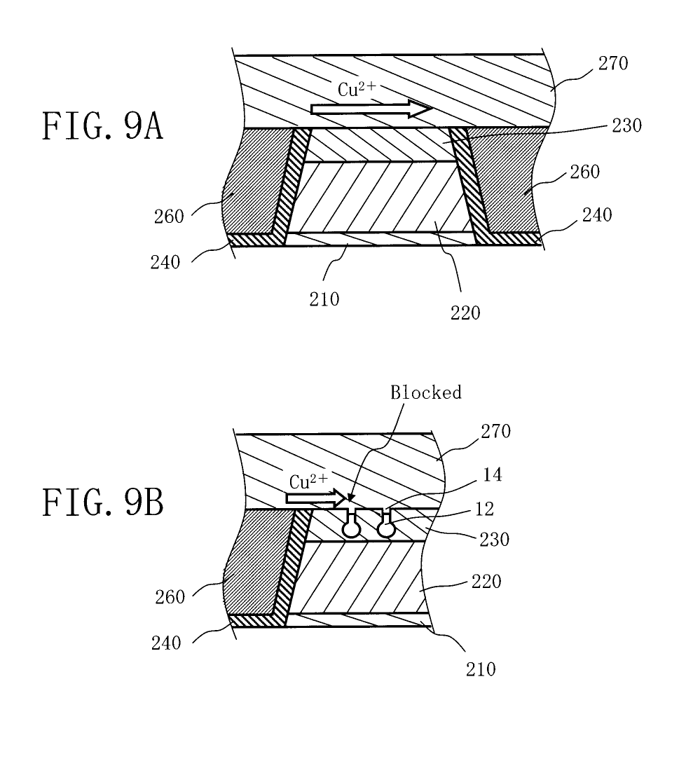

FIGS. 9A and 9B are conceptual sectional views comparing conditions of the Cu drift depending on presence/absence of intrusion into the diffusion barrier film of the first embodiment. If the diffusion barrier film 270 does not intrude into the cap film 230 and the interface between the diffusion barrier film 270 and the cap film 230 is only a plane as shown in FIG. 9A, a drift of Cu ions will occur if a strong electric field is generated between wires formed by the two Cu films 260. In the first embodiment, in contrast, the diffusion barrier film 270 intrudes into the cap film 230 and thus, even if the electric field is strong enough to cause a drift of Cu ions as shown in FIG. 9B, intruded portions act as an obstacle for Cu ions to proceed, making Cu ions less likely to reach the adjacent Cu wire. Thus, a drift of Cu ions can be suppressed by making a portion of the diffusion barrier film 270 intrude into the cap film 230 to make the interface therebetween non-plane.

In the first embodiment, a drift of Cu ions can be suppressed not only by making the relative dielectric constant k2 of the cap film 230 smaller than the relative dielectric constant k1 of the low-k film 220, but also by making a portion of the diffusion barrier film 270 intrude into the cap film 230 to make the interface therebetween non-plane.

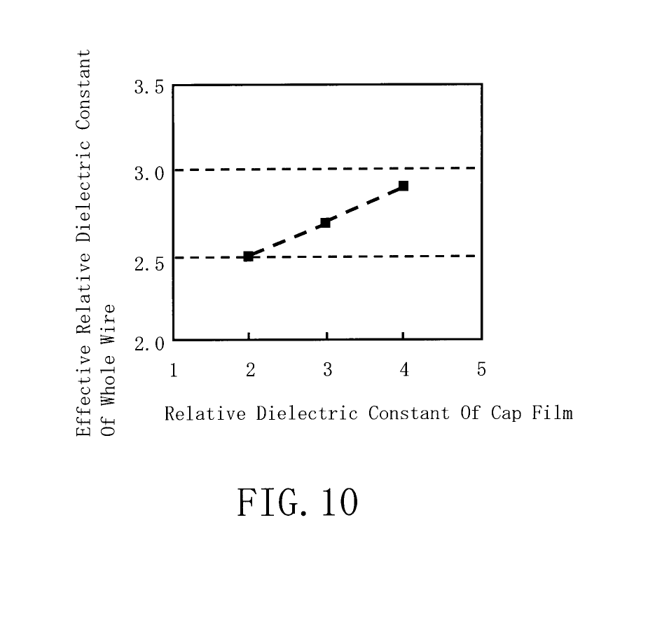

FIG. 10 is a diagram showing a result of simulating a relationship between the relative dielectric constant of the cap film of the first embodiment and the effective relative dielectric constant of whole of one wiring layer. In FIG. 10, the vertical axis shows the effective relative dielectric constant of a whole wiring layer and the horizontal axis shows the relative dielectric constant of the cap film 230. The effective dielectric constant is calculated by a two-dimensional electromagnetic simulation. It is assumed also here that the relative dielectric constant k of the low-k film 220 is 2.7 and that of the diffusion barrier film 270 is 3.7 to determine results by calculating the line capacity in a dense wiring structure having a pitch of 140 nm between a wire portion and an insulation portion. As a result, the effective dielectric constant can be reduced by lowering the dielectric constant of the cap film 230 as shown in FIG. 10.

In the first embodiment, as described above, the dielectric constant can be further reduced as a whole wiring layer comparing to the conventional technique by making the relative dielectric constant k2 of the cap film 230 smaller than the relative dielectric constant k1 of the low-k film 220.

### Second Embodiment

In the first embodiment, a structure in which a portion of the diffusion barrier film 270 is caused to intrude into the cap film 230 by forming the diffusion barrier film 270 on the cap film 230 in a porous state with the pores 12 and the vent holes 14. However, the cap film 230 is not limited to a porous film. In the second embodiment, a cap film that is not a porous film will be described.

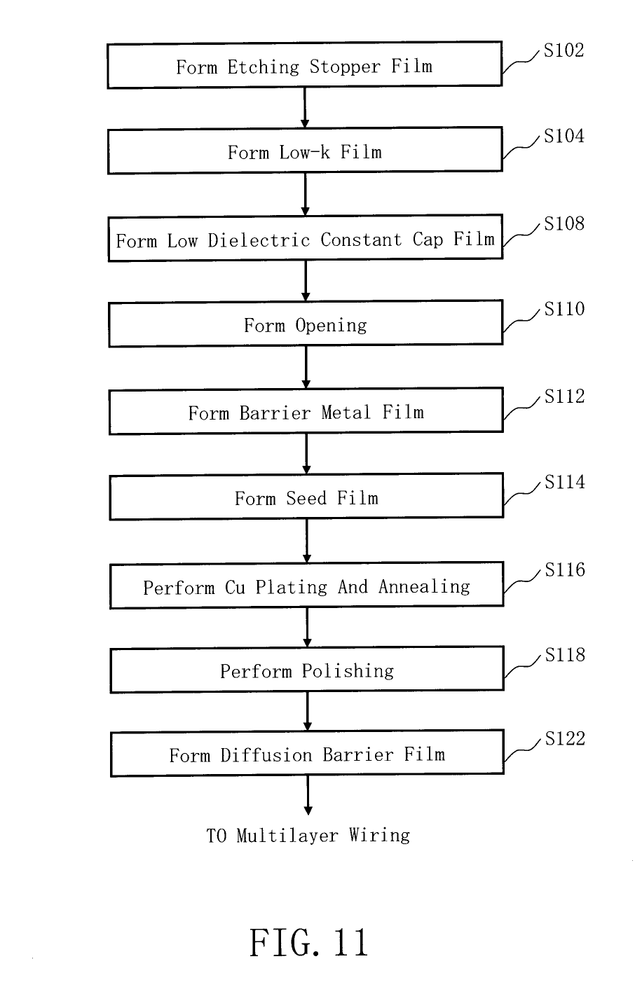

FIG. 11 is a flow chart showing principal parts of the method for fabricating a semiconductor device in the second embodiment. In FIG. 11, the method for fabricating a semiconductor device is the same as that in FIG. 1 except that a low dielectric constant cap film formation process (S108) is added in place of the porogen containing cap film formation process (S106) and the porogen removal process (S120) is eliminated. Detail of each of processes from the etching stopper film formation process (S102) to the low-k film formation process (S104) is the same as that in the first embodiment.

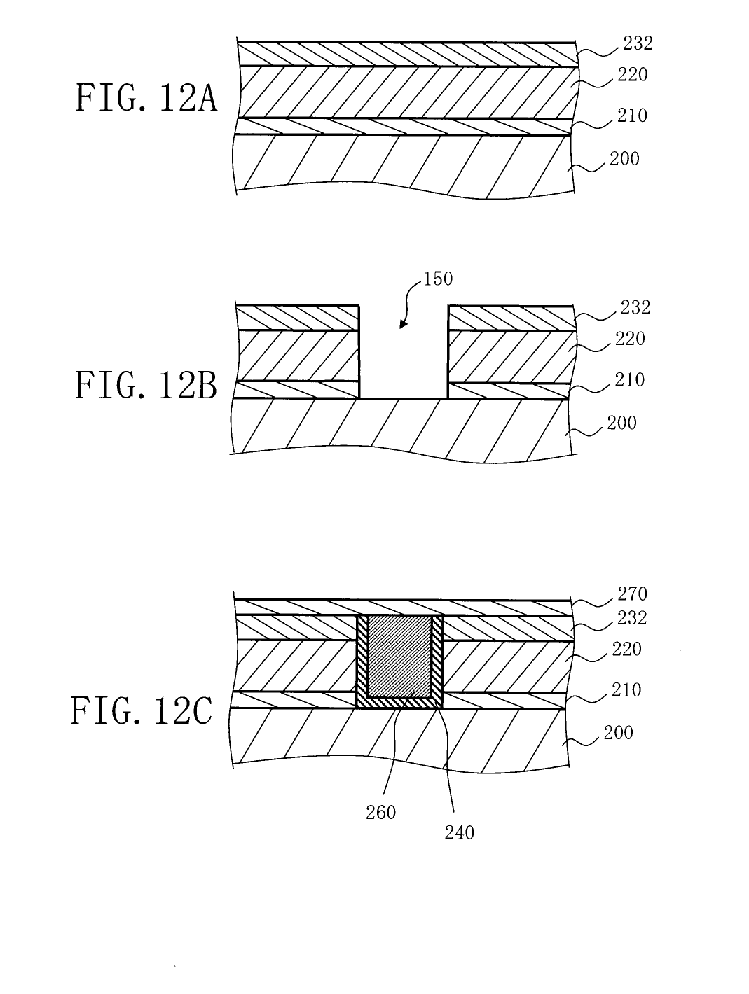

FIGS. 12A to 12C are process sectional views showing processes performed corresponding to the flow chart in FIG. 11. FIGS. 12A to 12C show processes from the low dielectric constant cap film formation process (S108) to the opening formation process (S110), and the diffusion barrier film formation process (S122) respectively.

As shown in FIG. 12A, as the low dielectric constant cap film formation process (S108), a cap film 232 is formed on the low-k film 220 to a thickness of 20 to 40 nm using a low dielectric constant material. For example, the SOD method is used to form the cap film 232. The cap film 232 is formed to have a thickness thinner than that of the low-k film 220. A material that does not require removal of porogen as a post-process and that has a lower dielectric constant than that of the low-k film 220 even without pores inside is used as a material of the cap film 232. Instead of the above SiOCH based material, for example, a polymer material containing carbon (C) is preferable. For example, a polymer material containing carbon fluoride (CF) is preferable. Using such a material, the cap film 232 whose relative dielectric constant k is 1.5 to 2.0, which is lower than that of the low-k film 220, can be obtained. The formation method is not limited to the SOD method, and the CVD method may also be used.

As shown in FIG. 12B, as the opening formation process (S110), the opening 150 to be a wire groove or a via hole is formed by selectively etching the exposed cap film 232 and the low-k film 220 in a lower layer thereof by the anisotropic etching method using a resist pattern (not shown) as a mask. In this case, the etching is performed using the etching stopper film 210 as an etching stopper. Then, the etching stopper film 210 is etched to form the opening 150 reaching the substrate 200. Other details of this process are the same as those in the first embodiment. For example, if the opening 150 is formed by using the RIE method, the cap film 232 having weak mechanical strength and the low-k film 220 thereunder may be protected by adjusting the bias voltage or the like. Each of the subsequent processes from the barrier metal film formation process (S112) to the polishing process (S118) is the same as that in the first embodiment. In the polishing process (S118), the cap film 232 with weak mechanical strength may be protected by adjusting the polishing load or slurry.

As shown in FIG. 12C, as the diffusion barrier film formation process (S122), the diffusion barrier film 270 (barrier film) for preventing diffusion of Cu is formed on the cap film 232 by using the CVD method. For example, the diffusion barrier film 270 is formed on the cap film 232 to a thickness of 20 to 40 nm. Here, no pore exists in the cap film 232 and thus, the diffusion barrier film 270 is deposited on the cap film 232 without intruding into the cap film 232. Other details of this process are the same as those in the first embodiment.

According to the processes described above, a wiring layer for one layer in which the relative dielectric constant k2 of the cap film 232 is made smaller than the relative dielectric constant k1 of the low-k film 220 can be formed. Even in such a case, as described in FIGS. 6 to 8, a drift of Cu ions can be suppressed. As a result, the TDDB life can be prolonged. Moreover, as described with reference to FIG. 10, the dielectric constant can be further lowered as a whole Cu wiring layer.

In the description above, in addition to Cu, a material that is used in the semiconductor industry and has Cu as a main component such as a Cu—Sn alloy, Cu—Ti alloy or Cu—Al alloy can be used to achieve similar effects.

In the foregoing, embodiments have been described with reference to concrete examples. However, the present invention is not limited to these concrete examples. In the above examples, for example, a case in which a wiring layer for one layer is formed by the single damascene method is described, but the present invention can also be applied similarly to a low-k film to be a main dielectric film and a cap film to be positioned on the side in an upper part of a wire when the wire and a via plug are simultaneously formed by the dual damascene method. Also, the present invention can be applied similarly to a cap film and a diffusion barrier metal formed thereon by the dual damascene method.

Concerning the thickness of interlayer dielectric film and the size, shape, number of electrodes, and the like what is needed for semiconductor integrated circuits and various semiconductor elements can be appropriately selected and used.

In addition, the scope of the present invention covers all semiconductor devices that have elements of the present invention and that can be obtained with appropriate design modification by persons skilled in the art and methods for fabricating the semiconductor devices.

While techniques normally used in the semiconductor industry, for example, a photolithography process and cleaning before and after treatment are not described for convenience of description, it is needless to say that such techniques are included in the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for fabricating a semiconductor device, comprising:
forming a dielectric film above a substrate;
forming a cap film, in which pores are formed, on the dielectric film;
forming an opening in the cap film and the dielectric film;
depositing a conductive material inside the opening; and
forming a diffusion barrier film for preventing diffusion of the conductive material on the cap film, after the conductive material is deposited inside the opening, in such a way that a portion of the diffusion barrier film intrudes into the cap film and that a portion of the pores remains.

2. The method according to claim 1, wherein when the cap film is formed, a material containing porogen components is used to form the cap film in such a way that the porogen components remain, the method further comprising:
removing the porogen components from inside the cap film after the conductive material is deposited inside the opening and before the diffusion barrier film is formed.

3. The method according to claim 2, wherein a porous cap film having a relative dielectric constant lower than that of the dielectric film is obtained by removing the porogen components.

4. The method according to claim 2, wherein the portion of the diffusion barrier film intrudes into vent holes formed when the porogen components are removed.

5. The method according to claim 1, wherein when the cap film is formed, a material containing porogen components is used to form the cap film in such a way that the porogen components remain and
when the opening is formed, the opening is formed in the cap film with the porogen components remaining.

6. The method according to claim 5, wherein when the conductive material is deposited, the conductive material is deposited inside the opening formed in the cap film with the porogen components remaining.

7. The method according to claim 6, wherein when the conductive material is deposited, the conductive material is deposited on the cap film with the porogen components remaining and the conductive material on the cap film is removed by polishing.

8. The method according to claim 7, wherein when the conductive material is removed by polishing, the conductive material is polished while the porogen components remain in the cap film.

9. The method according to claim 7, further comprising removing the porogen components from inside the cap film after the conductive material is removed by polishing and before the diffusion barrier film is formed.

10. The method according to claim 8, wherein a cap film having a density lower than that of the dielectric film is obtained by removing the porogen components.

11. A method for fabricating a semiconductor device, comprising:
forming a dielectric film above a substrate;
forming a cap film by using a material containing porogen components on the dielectric film so that the porogen components remain;
forming an opening in the cap film and the dielectric film;
depositing a conductive material inside the opening; and
obtaining a porous cap film having a relative dielectric constant lower that that of the dielectric film by removing the porogen components from inside the cap film after the conductive material is deposited inside the opening.

12. The method according to claim 11, wherein when the conductive material is deposited, the conductive material is deposited on the cap film with the porogen components remaining and the conductive material deposited on the cap film with the porogen components remaining is removed by polishing.

13. The method according to claim 12, wherein when the conductive material is removed by polishing, the conductive material is polished while the porogen components remain in the cap film.

14. The method according to claim 13, wherein when the conductive material is removed by polishing, the conductive material is polished until a surface of the cap film is exposed.

15. The method according to claim 14, wherein the porogen components are removed by irradiating the surface of the cap film exposed with an electron beam.

16. The method according to claim 14, wherein the porogen components are removed by irradiating the surface of the cap film exposed with ultraviolet rays.

17. The method according to claim 11, further comprising forming a diffusion barrier film for preventing diffusion of the conductive material on the porous cap film in such a way that a portion of the diffusion barrier film intrudes into the porous cap film.

18. The method according to claim 17, wherein the portion of the diffusion barrier film intrudes into vent holes formed when the porogen components are removed.

19. A semiconductor device, comprising:
a dielectric film formed above a substrate;
a cap film formed on the dielectric film and having a relative dielectric constant lower than that of the dielectric film; and
a wire arranged in such a manner that the cap film and the dielectric film are positioned on a side of the wire.

20. The semiconductor device according to claim 19, further comprising a diffusion barrier film formed on the wire and the cap film in such a way that a portion thereof intrudes into the cap film, the diffusion barrier film preventing diffusion of a material of the wire.
